(19) United States
(12) Patent Application Publication
(10) Pub. No.: US 2009/0280248 A1
(43) Pub. Date: Nov. 12, 2009

(54) POROUS SUBSTRATE HOLDER WITH THINNED PORTIONS

(75) Inventors: Matthew G. Goodman, Chandler, AZ (US); Robert M. Vyne, Gilbert, AZ (US)

Correspondence Address: Knobbe, Martens, Olson & Bear LLP, 2040 Main Street, 14th Floor, Irvine, CA, 92614, US

(73) Assignee: ASM AMERICA, INC., Phoenix, AZ (US)

(21) Appl. No.: 12/116,114

(22) Filed: May 6, 2008

(51) Int. Cl. C23C 16/44

(52) U.S. Cl. 427/255.28; 118/728

(57) ABSTRACT

A substrate support system comprises a substrate holder for supporting a substrate. The substrate holder comprises a central portion sized and shaped to extend beneath most or all of a substrate supported on the substrate holder. The central portion has one or more recesses defining thinned portions of the central portion. The one or more thinned portions may comprise at least about 10% of an upper or lower surface of the central portion. The central portion is formed of a porous material, such as a material having a porosity between about 10-40%, configured to allow gas flow therethrough.

### BACKGROUND

1. Field of the Invention

The present invention relates to semiconductor substrate handling systems and, in particular, relates to systems and methods for supporting a substrate during material deposition processes.

2. Description of the Related Art

High-temperature ovens, or reactors, are used to process substrates for a variety of reasons. In the electronics industry, substrates, such as semiconductor wafers, are processed to form integrated circuits. In a reaction process, a substrate, typically a circular silicon wafer, is placed on a substrate holder. In some processes, the substrate holder helps to attract radiation and more evenly heat the substrate. These substrate holders are sometimes referred to as susceptors. The substrate and substrate holder are enclosed in a reaction chamber, typically made of quartz, and heated to high temperatures by a plurality of radiant heat lamps placed around the quartz chamber.

In an exemplary high temperature process, a reactant gas is passed over the heated substrate, causing the chemical vapor deposition (“CVD”) of a thin layer of the reactant material onto a surface of the substrate. As used herein, the terms “processing gas,” “process gas,” and “reactant gas” generally refer to gases that contain substances, such as silicon-containing gases, to be deposited on a substrate. As used herein, these terms do not include cleaning gases. Through subsequent processes, the layers of reactant material deposited on the substrate are made into integrated circuits. The process gas flow over the substrate is often controlled to promote uniformity of deposition across the top or front side of the substrate. Deposition uniformity can be further promoted by rotating the substrate holder and substrate about a vertical center axis during deposition. As used herein, the “front side” of a substrate refers to the substrate's top surface, which typically faces away from the substrate holder during processing, and the “backside” of a substrate refers to the substrate's bottom surface, which typically faces the substrate holder during processing.

As mentioned above, a typical substrate to be processed is comprised of silicon. In the production of integrated circuits, it is sometimes desirable to deposit additional silicon, for example via CVD, onto the substrate surface(s). If the additional silicon is deposited directly onto the silicon surface of the substrate, the newly deposited silicon maintains the crystalline structure of the substrate. This type of deposition is known as epitaxial deposition. However, the surfaces of the original substrate to be processed are typically polished on both sides. When brought into contact with an oxygen environment, a native oxide layer, such as SiO₂, is formed on the substrate. A deposition of silicon onto the native oxide layer forms polysilicon deposits. In order to conduct epitaxial deposition, it is ordinarily necessary to remove the native oxide layer from each of the substrate's top and/or bottom surfaces onto which new silicon is to be deposited. The native oxide layer is typically removed by exposing it to a cleaning gas, such as hydrogen gas (H₂), at a sufficiently high temperature, prior to the deposition of additional silicon. As used herein, the term “cleaning gas” is different than and does not encompass reactant gases.

There are a large variety of different types of substrate holders for supporting a substrate during processing. A typical substrate holder comprises a body with a generally horizontal upper surface that receives and/or underlies the supported substrate. A spacer or spacer means is often provided for maintaining a small gap between the supported substrate and the horizontal upper surface of the substrate holder. This gap prevents process gases from causing the substrate to stick to the substrate holder. The substrate holder often includes an annular shoulder that closely surrounds the supported substrate. One type of spacer or spacer means comprises a spacer element fixed with respect to the substrate holder body, such as an annular lip, a plurality of small spacer lips, spacer pins or nubs, etc. An alternative type of spacer element comprises a plurality of vertically movable lift pins that extend through the substrate holder body and are controlled to support the substrate above the upper surface of the substrate holder. Often, the spacer element is positioned to contact the substrate only within its “exclusion zone,” which is a radially outermost portion of the substrate within which it is difficult to maintain deposition uniformity. The exclusion zone is not used in the manufacturing of integrated circuits for commercial use, due to the non-uniformity of deposition there. A processed substrate may be characterized, for example, as having an exclusion zone of five millimeters from its edge.

One problem associated with CVD is the phenomenon of “backside deposition.” Many substrate holders are unsealed at the substrate perimeter so that process gases can flow down around the peripheral edge of the substrate and into the gap between the substrate and the substrate holder. These process gases tend to deposit on the substrate backside, both as nodules and as an annular ring at or near the substrate edge. This undesirable deposition creates non-uniformities in substrate thickness, generally detected by local site flatness tools. Such non-uniformities in substrate thickness can adversely affect chucking down of the substrate, and thus make impossible subsequent processing steps, such as photolithography.

Prior to epitaxial deposition, the front side of the substrate is typically exposed to a cleaning gas, such as H₂, to remove the native oxide layer. However, the unsealed substrate perimeter permits limited cleaning gas to contact the backside of the substrate, thus resulting in oxide removal on the substrate backside. The amount of cleaning gas that contacts the substrate backside is ordinarily not sufficient to remove the entire oxide layer from the backside in a typical timeframe for native oxide removal from the substrate front side. However, at some locations, the cleaning gas tends to create pinhole openings in the oxide layer on the substrate backside, exposing the silicon surface. In particular, the pinhole openings tend to form in an annular ring or “halo.” The longer the exposure to cleaning gas, the further inward the cleaning gas effuses radially toward the center of the substrate, creating more pinhole openings in the oxide layer. Some of the removed oxide can redeposit onto the oxide layer of the substrate backside to form a concentrated area of SiO₂ at the center portion of the substrate. Once deposition begins, the process gases can similarly effuse around the substrate edge from above the substrate. The partial native oxide removal can result in mixed deposition of process gas materials on the substrate backside—epitaxial deposition on the exposed silicon surfaces and polysilicon deposition on the oxide layer. The halo's intensity is based on the concentrations of Sio₂ and non-depleted process gases, resulting in small polysilicon growths or bumps. These bumps of polysilicon scatter light, showing a thick haze under bright light.

One method for reducing backside deposition involves the use of a purge gas that flows upwardly from between the substrate holder and substrate and around the substrate edge to reduce the downward flow of cleaning or process gases. For example, U.S. Pat. No. 6,113,702 to Halpin et al. discloses a two-piece susceptor supported by a hollow gas-conveying spider. The two pieces of the susceptor form gas flow passages therebetween. During deposition, an inert purge gas is conveyed upwardly through the spider into the passages formed in the susceptor. The purge gas flows upwardly around the substrate edges and partially inhibits the flow of process gases to the substrate backside. Conventional substrate holder systems and methods for preventing backside deposition can in some circumstances limit the uniformity of deposition. Conventional purge gas systems typically include gas flow channels to allow for the flow of purge gas through the substrate holder. These channels can result in the direct impingement of relatively focused, high velocity flows of purge gas onto the substrate backside. These focused, high velocity flows of purge gas onto the substrate backside can cause localized cooling or “cold spots” in the substrate, which adversely affect the uniformity of deposited materials on the substrate.

Another problem in semiconductor processing is known as autodoping. Autodoping can cause undesired variations in dopant concentration on the substrate, particularly in high-temperature epitaxial deposition processes. The formation of integrated circuits involves the deposition of dopant material, such as doped silicon, onto the front side of the substrate. Autodoping is the tendency of dopant atoms to diffuse downwardly through the substrate, emerge from the substrate backside, and then travel between the substrate and the substrate holder up around the substrate edge to redeposit onto the substrate front side, typically near the substrate edge. These redeposited dopant atoms adversely affect the performance of the integrated circuits, particularly semiconductor dies from near the substrate edge. Autodoping tends to be more prevalent and problematic for higher-doped substrates.

One method of reducing autodoping involves a susceptor that has a plurality of holes that permit the flow of gas between the regions above and below the susceptor. Autodoping is reduced by directing a flow of inert gas horizontally underneath the susceptor. Some of the gas flows upwardly through the holes of the susceptor into a gap region between the susceptor and a substrate supported by the susceptor. As diffused dopant atoms emerge at the substrate backside, they become swept away by the gas downwardly through the holes in the susceptor. In this way, the dopant atoms tend to get drawn down into the region below the susceptor. Exemplary references disclosing conventional substrate holders employing this method are U.S. Pat. No. 6,444,027 to Yang et al. and U.S. Pat. No. 6,596,095 to Ries et al.

However, the systems disclosed in the patents to Yang et al. and Ries et al. are not designed to prevent backside deposition of reactant gases. These systems require a relatively large flow of gas underneath the substrate holder to sweep out the out-diffused dopant atoms from the backside of the supported substrate through the holes in the substrate holder. Also, these systems typically require a completely or nearly fluid-tight separation between the regions above and below the substrate holder in order to prevent reactant gases from flowing underneath the substrate holder and upward through the substrate holder holes to the substrate backside. Unfortunately, it is often very difficult to provide a completely fluid-tight separation between the regions above and below the substrate holder. Divider plates are typically provided, but some clearance usually remains, particularly if the substrate holder is designed to be rotated during processing. Thus, with these systems, there is a significant risk of deposition of reactant gases on the substrate backside.

Another method of reducing autodoping and backside deposition is disclosed in U.S. Patent Application Publication No. US-2005-0193952-A1 to Goodman et al. This method involves a substrate holder having a plurality of holes that permit the flow of gas between the regions above and below the holder, in combination with a gas-conveying support structure that delivers an inert gas through some but not all of those holes to a gap region between the holder and a substrate supported thereon. The forced flow of inert gas into the gap region sweeps diffused dopant atoms downward through certain ones of the holes, to prevent autodoping. Also, some of the inert gas flow to the gap region flows upward around the substrate edge to inhibit backside deposition of reactant gases.

Another method of reducing autodoping and backside deposition involves a susceptor formed of a porous material, as described in U.S. Patent Application Publication No. US-2004-0266181-A1 to Schauer et al. The susceptor is permeable to gas only on account of the porosity of the material.

### SUMMARY

In accordance with an embodiment, a substrate support system is provided. The system comprises a substrate holder for supporting a substrate. The substrate holder includes a central portion such that the substrate is spaced apart from the central portion when the substrate is supported by the substrate holder. The central portion has one or more recesses defining thinned portions of the central portion. The central portion is formed of a material having a porosity between about 10%-40% and configured to allow gas flow therethrough.

In accordance with another embodiment, a substrate support system is provided. The substrate support system includes a substrate holder for supporting a substrate. The substrate holder comprises a central portion having an upper surface, a lower surface, and a plurality of recesses. Each recess is formed in one of the upper surface and the lower surface. Each recess defines a thinned portion of the central portion. The central portion formed of a porous material.

In accordance with yet another embodiment, a method is provided for processing a substrate. A substrate holder is provided. The substrate holder includes a central portion having one or more recesses defining thinned portions of the central portion. The one or more thinned portions comprise are configured to allow gas flow therethrough. A substrate is rested onto the substrate holder so that a gap region is formed between an upper surface of the central portion and a bottom surface of the substrate. An inert or cleaning gas is directed through the one or more thinned portions of the substrate holder.

In accordance with still another embodiment, a substrate holder for supporting a substrate is provided. The substrate holder comprises a central portion having an upper surface, a lower surface, and a plurality of recesses each formed in one of the upper surface and the lower surface. Each recess defines a thinned portion of the central portion. The central portion is formed of a porous material configured to permit gas flow therethrough without allowing light to pass therethrough. The central portion includes at least one through-hole configured to receive an upward flow of gas.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the present invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

These and other aspects of the invention will be readily apparent to the skilled artisan in view of the description below, the appended claims, and from the drawings, which are intended to illustrate and not to limit the invention, and wherein:

FIG. 1 is a schematic, cross-sectional view of an exemplary reaction chamber with a substrate supported on a substrate holder therein.

FIG. 2A is a top perspective view of a substrate holder according to one embodiment.

FIG. 2B is a bottom perspective view of the substrate holder of FIG. 2A.

FIG. 3A is a top perspective view of a substrate holder according to another embodiment.

FIG. 3B is a bottom perspective view of the substrate holder of FIG. 3A.

FIG. 4 is a top plan view of a substrate holder according to another embodiment.

FIG. 5A is a partial cross-sectional view of the substrate holder of FIG. 2A, taken along line 5A-5A thereof.

FIG. 5B is an enlarged top view of an edge of the substrate holder of FIG. 5A.

FIG. 6 is a top view of a substrate support system according to an embodiment.

FIG. 7 is a cross-sectional view of the substrate support system of FIG. 6, taken along lines 7-7 thereof.

FIG. 8 is a side cross-sectional view of a substrate support system according to another embodiment.

FIG. 9 is a top view of the substrate holder support of the substrate support system of FIG. 8.

FIG. 10 is a side cross-sectional view of a substrate support system according to a yet another embodiment.

### DETAILED DESCRIPTION OF PREFERRED EMBODIMENTS

The following detailed description of the preferred embodiments and methods presents a description of certain specific embodiments to assist in understanding the claims. However, one may practice the present invention in a multitude of different embodiments and methods as defined and covered by the claims.

Referring more specifically to the drawings for illustrative purposes, the present invention is embodied in the devices generally shown in the Figures. It will be appreciated that the apparatuses may vary as to configuration and as to details of the parts, and that the methods may vary as to the specific steps and sequence, without departing from the basic concepts as disclosed herein.

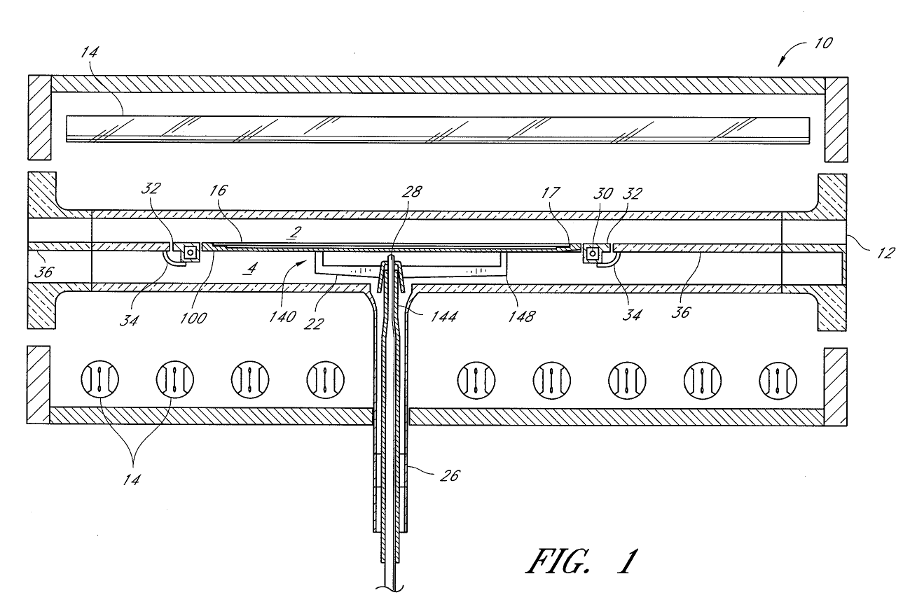

Prior to describing certain embodiments of the substrate holder, an exemplary CVD reactor is disclosed. FIG. 1 illustrates an exemplary CVD reactor 10, including a quartz reaction chamber 12. Radiant heating elements 14 are supported outside the transparent chamber 12 to provide heat energy to the chamber 12 without appreciable absorption by the chamber walls. Although the embodiments are described in the context of a “cold wall” CVD reactor, it will be understood that the substrate support systems described herein can be used in other types of reactors and semiconductor processing equipment. Skilled artisans will appreciate that the claimed invention is not limited to use within the particular reactor 10 disclosed herein. In particular, one of ordinary skill in the art can find application for the substrate support systems described herein for other semiconductor processing equipment, wherein a substrate is supported while being heated, cooled, or processed. Moreover, while illustrated in the context of standard silicon wafers, the substrate holders described herein can be used to support other kinds of substrates, such as glass substrates which are subjected to treatments, such as CVD, physical vapor deposition (“PVD”), etching, annealing, dopant diffusion, or photolithography. The substrate holders are of particular utility for supporting substrates during treatment processes at elevated temperatures. Also, skilled artisans will appreciate that the embodiments described herein include substrate holders that are susceptors as well as those that are not susceptors. An alternative exemplary reaction chamber suitable for the substrate support system of this invention is described in U.S. Pat. No. 6,093,252 to Wengert et al.

The radiant heating elements 14 typically include two banks of elongated tube-type heating lamps arranged in orthogonal or crossed directions above and below a substrate holder holding a substrate 16. Each of the upper and lower surfaces of the substrate can face one of the two banks of heating lamps 14. According to an embodiment, a controller within the thermal reactor adjusts the relative power to each lamp 14 to maintain a desired temperature during wafer processing. There may also be spot lamps (not shown) that are used for compensating for the heat sink effect of lower holder structures.

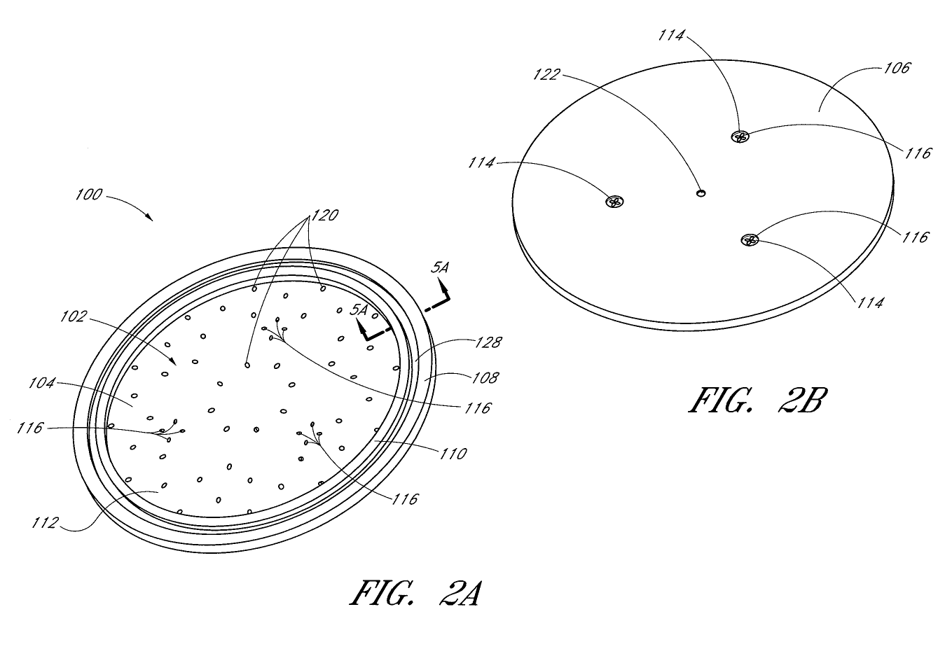

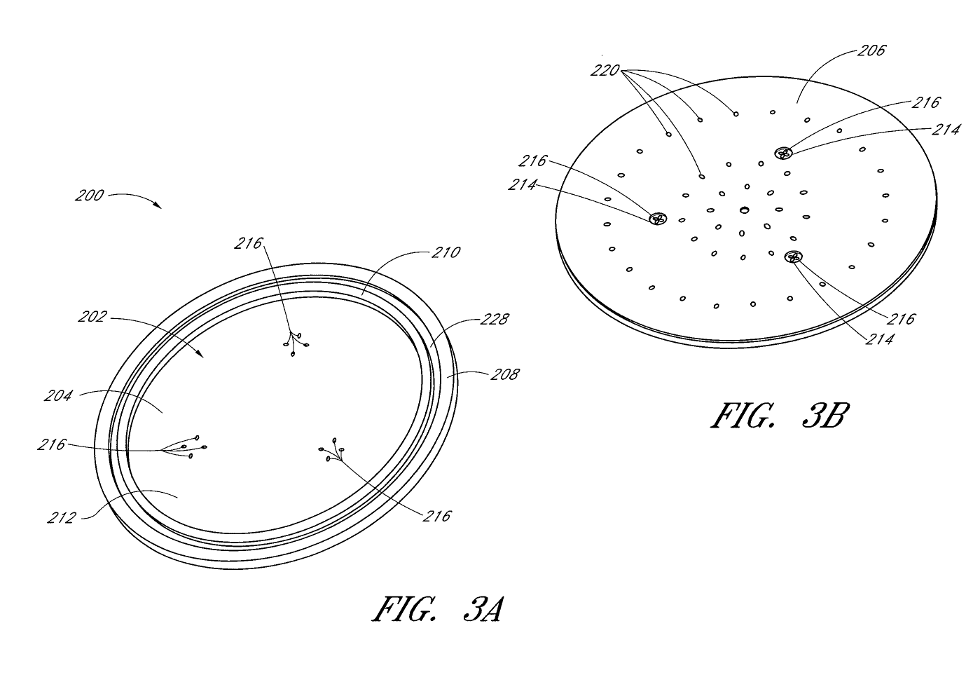

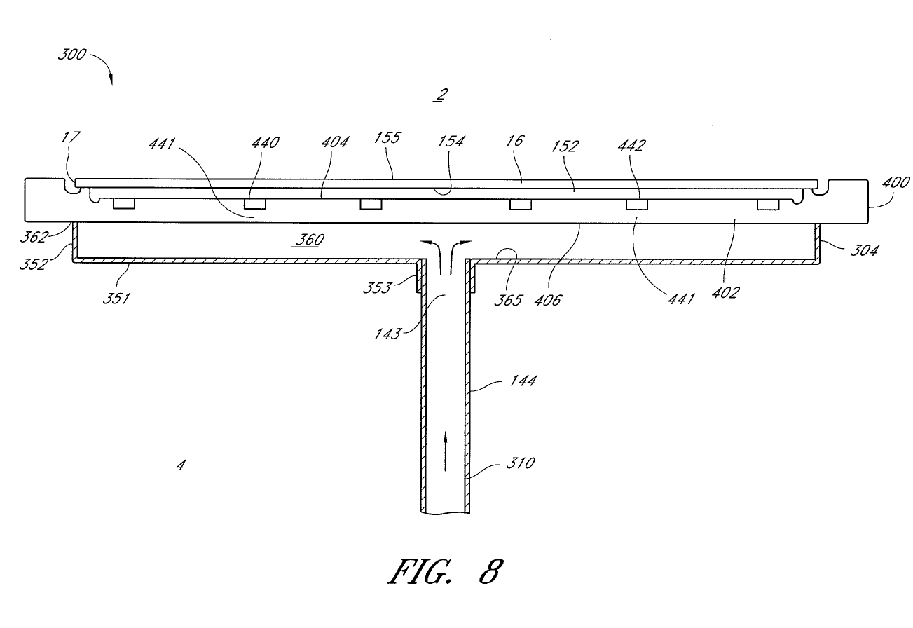

The illustrated substrate 16 includes a generally circular edge 17, shown in FIG. 1, supported within the reaction chamber 12 upon a substrate support system 140. The illustrated substrate support system 140 includes a substrate holder 100, upon which the substrate 16 rests, and a hollow spider 22 that supports the substrate holder 100. Several embodiments of the substrate holder 100 are shown in greater detail in FIGS. 2-5, which are described below. The substrate support system 140 is shown in greater detail in FIGS. 6 and 7. The spider 22 can be formed of a transparent and non-metallic material. The skilled artisan will appreciate that the non-metallic aspect of the material helps to reduce contamination. In the illustrated embodiment, the spider 22 is mounted to a gas-conveyor 144, such as a tube or shaft, which extends downwardly through a tube 26 depending from the lower wall of the chamber 12. The spider 22 has at least three hollow substrate support arms 148, which extend radially outwardly and upwardly from the shaft 144. The arms 148 can be separated by equal angles about a vertical center axis of the shaft 144, which can be aligned with a vertical center axis of the substrate holder 100 and wafer 16. For example, if there are three arms 148, they can be separated from one another by about 120°. The arms 148 are configured to support the bottom surface of the substrate holder 100. In an embodiment, the substrate holder 100 comprises a susceptor capable of absorbing radiant energy from the heating elements 14 and re-radiating such energy. The substrate holder 100 can be solid and formed of a single piece. Alternatively, the substrate holder 100 can be formed of multiple pieces that are assembled or attached together. According to an embodiment, the gas-conveyor 144, the spider 22, and the substrate holder 100 are configured to rotate in unison about a vertical center axis during substrate processing.

A central temperature sensor or thermocouple 28 may be provided for sensing the temperature at the center of the substrate holder 100. In the illustrated embodiment, the temperature sensor 28 extends through the gas-conveyor 144 and the spider 22 and is located in proximity to the substrate holder 100. Additional peripheral temperature sensors or thermocouples 30 are also shown housed within a slip ring or temperature compensation ring 32, which surrounds the substrate holder 100 and the wafer 16. The thermocouples 28, 30 are connected to a temperature controller (not shown), which controls and sets the power of the various radiant heating elements 14 in response to the temperature readings of the thermocouples 28, 30.

In addition to housing the thermocouples 30, the slip ring 32 also absorbs radiant heat during high temperature processing. The heated slip ring 32 helps to reduce heat loss at the wafer edge 17. The slip ring 32 can be suspended by any suitable means. For example, the illustrated slip ring 32 rests upon elbows 34, which depend from the quartz chamber dividers 36. As illustrated, the dividers 36 divide the reactor 10 into an upper chamber 2 designed for the flow of reactant or process gases, for example for CVD on the substrate surface, and a lower chamber 4. The dividers 36 and other elements of the reactor 10 can substantially prevent fluid communication between the chambers 2 and 4. However, because the substrate holder 100 can be rotatable about a vertical center axis, a small clearance typically exists between the substrate holder 100 and the slip ring 32 or other elements. Thus, it is often difficult to completely prevent fluid communication between the upper chamber 2 and the lower chamber 4. This problem is typically addressed by creating a pressure differential between the chambers 2, 4, such that pressure is higher in the lower chamber 4 to inhibit downward flow of gases from the upper chamber 2 to the lower chamber 4.

FIGS. 2A and 2B are top and bottom perspective views, respectively, of one embodiment of the substrate holder 100. The illustrated substrate holder 100 can be formed in one piece and is generally circular and disk-shaped. The illustrated embodiment of the substrate holder 100 includes a central portion 102 having an upper surface 104 and a lower surface 106. The upper surface 104 can be generally flat or planar, or it can alternatively be concave.

The upper surface 104 of the substrate holder 100 can include one or more spacers having upper surfaces configured to support a peripheral portion of the backside of a semiconductor substrate 16 (the substrate 16 is shown in FIG. 1) so as to produce a gap between the backside surface 154 (FIG. 7) of the substrate and the upper surface 104 of the substrate holder 100. As shown in FIG. 2A, a single, unbroken, annular, ring-shaped spacer 110 is provided, which surrounds or encircles the upper surface 104 of the central portion 102. In other embodiments, the spacer 110 comprises multiple portions interrupted by openings, such multiple spacer portions collectively encircling the recesses or cut-outs 120 (discussed below) in the substrate holder 100. In still other embodiments, a ring of spacer veins is provided, which define separate channels therebetween. Such spacer veins can be oriented at an angle from the radial direction. Further details on such a ring of spacer veins can be found in U.S. Patent Application Publication No. US-2005-0092439-A1. An unbroken spacer 110 can substantially seal the perimeter of a supported substrate 16. While the interface between the annular spacer 110 and a supported substrate 16 is not airtight, it nevertheless hinders the flow of reactant gases from upper chamber 2 (FIG. 1) downwardly around the substrate edge 17 to the bottom surface 154 of the substrate. The upper surface of the spacer 110 (or multiple spacers in other embodiments) can be polished to prevent or minimize scratching of the backside of the substrate 16. According to an embodiment, the spacer 110 (or multiple spacers) contacts the substrate 16 only within its exclusion zone.

With continued reference to FIG. 2A, a raised annular shoulder 108 can surround the spacer 110. The shoulder 108 defines a substrate pocket 112 that receives the substrate 16 (FIG. 1), which is supported on the spacer 110. In an embodiment, the substrate holder 100 is a susceptor capable of absorbing radiant energy and transmitting it to the supported substrate 16.

With reference to FIG. 2B, the lower surface 106 of the central portion 102 of the illustrated substrate holder 100 includes a plurality of support recesses 114 that are each sized and configured to receive an upper end of an arm 148 of the hollow multi-armed support spider 22 (the spider 22 is shown in FIGS. 1 and 7). The number of support recesses 114 can be equal to the number of arms 148 of the spider 22. Each support recess 114 can be sized to receive a corresponding substrate arm 148 snugly, to minimize the escape of gas, as described below. However, a loose fit is also acceptable in other embodiments. According to an embodiment, the support recesses 114 are separated by substantially equal angular intervals about the center of the substrate holder 100. In the illustrated embodiment, the three support recesses 114 are separated by angular intervals of about 120°. The support recesses 114 can be radially positioned far enough from the center of the substrate holder 100 to permit the spider 22 to provide stable support to the substrate holder 100, but not so far as to introduce a risk of the spider arms 148 sagging due to excessive moment forces, which is known to occur in some systems.

In an embodiment, the substrate holder 100 is formed of a porous material, which allows fluid transfer therethrough. In one embodiment, the porosity of the porous material is between about 10-40%. In another embodiment, the porosity of the porous material is between about 20-30%. Such porosity of the substrate holder 100 allows sufficient flow therethrough of gas in thinned portions formed by recesses or cut-outs in the upper surface 104 or lower surface 106. Such gas flow prevents or reduces backside deposition and autodoping, as will be described in more detail below. According to an embodiment, the porous material is a composite silicon carbide material, such as one available from XyCarb Ceramics/Schunck Semiconductor of The Netherlands. In an embodiment, the porous material has a density in a range of about 0.5-1.5 g/cm³, such as about 1.0 g/cm³.

The skilled artisan will appreciate that there are problems associated with conventional porous substrate holders. For example, if the substrate holder having a uniform thickness is too thick, not enough gas will pass through the substrate holder, but if such a substrate holder is too thin, the holder may not be strong enough and may be susceptible to breakage. The embodiments described herein provide a substrate holder that overcomes the problem mentioned above by having a sufficient amount of thinned portions to allow gas flow therethrough and thicker portions to provide sufficient mechanical strength. The porous material can also be chemically resistant enough such that it does not react with process gases, such as silicon-containing gases, or cleaning gases, and contaminate the substrate being processed. Thus, as will be described in more detail below, the substrate holder 100 can be provided with thicker portions for mechanical strength and thinned portions, formed by recesses or cut-outs, to facilitate fluid flow therethrough.

According to an embodiment, the substrate holder 100 has a thickness, in the thicker portions, in the range of about 0.1-0.5 inch. In another embodiment, the substrate holder 100 has a thickness, in the thicker portions, in the range of about 0.20-0.30 inch. According to yet another embodiment, the substrate holder 100 has a thickness, in the thicker portions, in the range of about 0.22-0.25 inch. The skilled artisan will appreciate that, as the porous material may be brittle, the substrate support 100 preferably has a minimum thickness, in the thicker portions, of about 0.1 inch to provide sufficient mechanical strength to withstand thermal gradients from either dropping the substrate 16 on the substrate holder 100 or from thermal cycling. The thicker portions may act as supporting ribs, but are preferably small enough in cross-section as to not allow thermal imaging seen in nanotopography results.

Conversely, the skilled artisan will also understand that for a substantial portion of the backside gas, such as cleaning or sweep gas, to flow through the substrate holder 100, the porous material must also be as thin as possible in certain areas. Thus, in an embodiment, the substrate holder 100 has thinned portions, formed by vertically adjacent recesses or cut-outs in the upper or lower surface of the substrate holder 100. Such thinned portions can have a thickness in the range of about 0.01-0.1 inch to facilitate fluid flow of, for example, purge gas, cleaning gas, etc., through the substrate holder 100. According to another embodiment, the thinned portions have a thickness in a range of about 0.02-0.07 inch. The thinned portions of the substrate holder 100 will be described in more detail below. The combination of the porous material and the thinned portions allows gas to flow downwardly through the substrate holder 100 to prevent or reduce backside deposition and autodoping, as will be described in more detail below.

As shown in FIG. 2A, the central portion 102 includes a plurality of recesses or cut-outs 120 in the upper surface 104 to produce thinned portions of the substrate holder 100 for facilitating fluid flow through the holder 100. It will be understood that a recess or cut-out is a hole or opening that does not extend completely through the substrate holder 100.

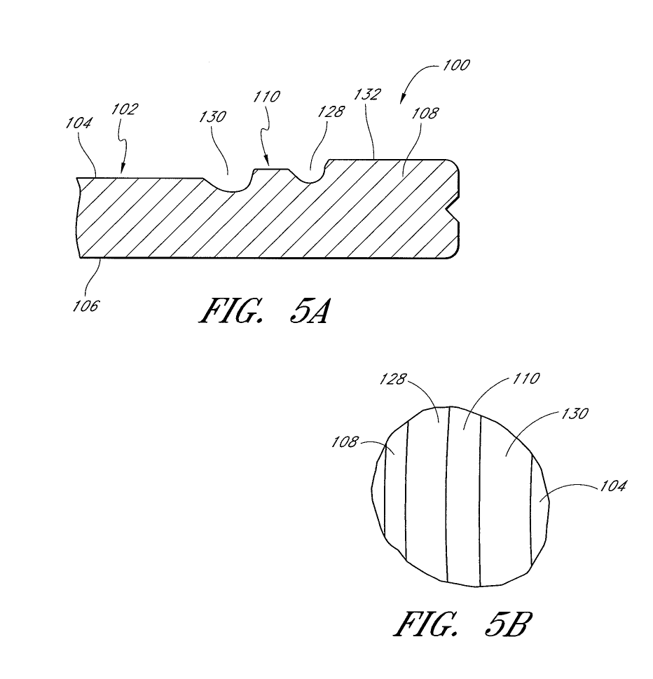

Alternatively, the central portion 102 of the substrate holder 100 may be provided with a plurality of thinned portions, such as cut-outs, of various shapes and sizes. For example, the upper surface 104 may have a honeycomb structure, such as that shown in FIG. 4, which is a top plan view of an embodiment of a substrate holder 800. According to this embodiment, cut-outs 818 are provided in the upper surface of the central portion 802 of the substrate holder 800 in a honeycomb arrangement. It will be understood that, in other embodiments, cut-outs may alternatively be provided in the lower surface (not shown) of the central portion 802. It can be seen in FIG. 4 that the thicker portions 808 between the cut-outs 818 can act as supporting ribs to provide mechanical strength to the substrate holder 800. It will be understood that the embodiment illustrated in FIG. 4 is merely an exemplary embodiment and that the wedge-shape of the cut-outs 818 is merely an exemplary shape. The skilled artisan will readily appreciate that other embodiments may have cut-outs of various shapes and sizes to provide the thinned portions of the substrate holder.

It will be understood that the thinned portions defined by recesses 120 allow a sufficient amount of gas, such as cleaning gas, purge gas, etc., to flow though the substrate holder 100 to reduce or prevent backside deposition as well as autodoping. The skilled artisan will also readily appreciate that recesses 120, in combination with the porous material, allow gas flow through the substrate holder, but do not allow direct gas flow on the backside of the substrate. As discussed above, direct impingement of relatively focused, high velocity flows onto the substrate backside can cause localized cooling or “cold spots” in the substrate, which adversely affect the uniformity of deposited materials on the substrate. Furthermore, the skilled artisan will appreciate that a substrate holder formed of the porous material has less thermal mass than a conventional substrate holder formed of a non-porous material, thereby increasing throughput as well as slip performance.

With reference to FIGS. 2A and 2B, the central portion 102 of the substrate holder 100 can also include a plurality of passages or holes 116 extending from the upper surface 104 to the lower surface 106. In the illustrated embodiment, there are twelve passages 116. The passages 116 can be inclined or angled with respect to vertical so that gas pumped upward through the passages 116 of one support recess 114 is directed away from the center of the support recess 114. According to an embodiment, the passages 116 can be inclined at an angle of within 30°-60° with respect to vertical. According to another embodiment, the passages 116 are inclined at an angle of about 45° with respect to vertical. It will be understood that, in other embodiments, recesses or cut-outs may be provided in place of the passages 116. As will be apparent to those skilled in the art, either open passages 116 or thinned regions of the substrate holder 100 are desirable to provide a flow path for the upward flow of gas through the spider 22.

In the illustrated embodiment, the recesses 120 in the upper surface 104 of the substrate holder 100 are located throughout the surface 104. Some of the illustrated recesses 120 are radially inward of the passages 116, while other recesses 120 are radially outward of the passages 116. Preferably, some of the recesses 120 are located near the substrate edge. Such radially outermost recesses 120 help to prevent backside deposition of reactant gases that flow downward around the substrate edge, because the outermost recesses 120 provide a flow path for the reactant gases to flow downward through the substrate holder 100 before depositing on the backside 154 (FIG. 7) of the substrate 16. In an alternative embodiment, all of the recesses 120 are positioned radially outward of the passages 116. The arrangement of recesses 120 may be axisymmetric with respect to the center axis of the substrate holder 100. Any suitable number of recesses 120 may be provided. It will be understood that there are a great variety of possible arrangements of the recesses 120 that define thinned portions in the central portion 102, and that the illustrated arrangement is merely one possibility. In one embodiment, about 20-80% of an upper or lower side of the substrate holder 100 has such thinned portions defined by recesses or cut-outs 120. The skilled artisan will appreciate that the recesses 120 and associated thinned portions can be uniformly distributed in the central portion 102 to provide a more uniform flow of gas through the substrate holder 100 and to provide more uniform mechanical strength from the thicker portions. In some embodiments, the thicker portions can act as supporting ribs.

In an embodiment, the central portion 102 has about 5000 recesses 120, each having a diameter of about 1 mm. According to some embodiments, the number of recesses 120 is between about 9-250. In other embodiments, the number of recesses is within about 6-225, between about 20-250, within about 50-200, within about 100-200, within about 100-250, or between about 80-5000. In an embodiment, the upper surface 104 of the central portion 102 has a density of recesses 120 within 0.01-3.0 recesses per cm². In other embodiments, the upper surface 104 of the central portion 102 has a density of recesses 120 in a range of about 0.05-2.5 recesses per cm², 0.10-2.5 recesses per cm², 0.20-2.5 recesses per cm², 0.50-2.0 recesses per cm², or 0.1-7 recesses per cm².

As shown in FIG. 2B, the lower surface 106 is a generally planar surface without any recesses 120. The illustrated holder 100 includes a center recess 122 configured to receive the central temperature sensor or thermocouple 28, which is shown in FIG. 1. In an embodiment, the recess 122 extends only partially through the substrate holder 100. As shown in FIG. 2B, the lower ends of the passages 116 are within the support recesses 114.

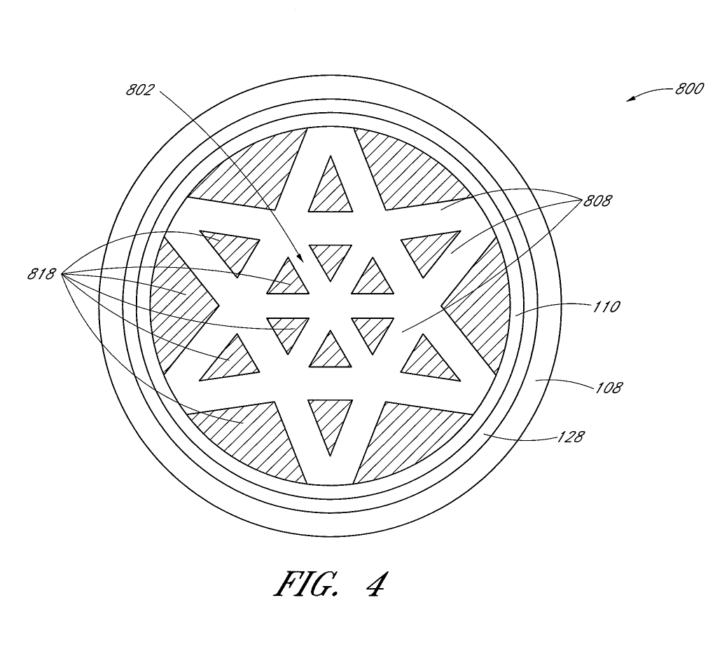

Another embodiment will be described with reference to FIGS. 3A and 3B. According to this embodiment, recesses or cut-outs 220 are provided on the lower surface 206 of the substrate holder 200. In this embodiment, as shown in FIG. 3A, the central portion 202 of the upper surface 204 is generally planar, without any recesses 220. As shown in FIG. 3B, the lower ends of completely open passages 216 are within the support recesses 214. In the illustrated embodiment, each support recess 214 includes the lower ends of four of the passages 216. The skilled artisan will appreciate that, in alternative embodiments, recesses 220 may be provided in place of passages 216 within the support recesses 214. As illustrated in FIG. 3B, the holder 200 can include a center recess 222 configured to receive the central temperature sensor or thermocouple 28, which is shown in FIG. 1.

According to this embodiment, as shown in FIG. 3A, the upper surface 204 does not have any recesses 220. Similar to the embodiment shown in FIG. 2A, the substrate holder 200 includes an annular, unbroken spacer 210 that supports the peripheral portion of the backside of a substrate 16, which is shown in FIG. 1. Alternatively, the spacer 210 can be formed of multiple spacers or even a ring of spacer veins. A raised annular shoulder 208 can surround the spacer 210, as shown in FIG. 3A. The shoulder 208 can define a substrate pocket 212 that receives the substrate 16.

For the embodiment shown in FIGS. 3A and 3B, the passages 216 can be inclined or angled with respect to vertical so that gas flowing upward through the passages 216 of one support recess 214 is directed away from the center of the support recess 214. In some embodiments, the passages 216 are inclined at an angle of between 30°-60° with respect to vertical, such as about 45°.

The passages 116, 216 and recesses 120, 220 can have cross-sections of various shapes. In practice, it is relatively easier to produce passages and recesses with circular cross-sections, by conventional drilling. In such embodiments, the diameter of the passages 116, 216 can be within about 0.02-0.15 inch, such as about 0.080 inch. The diameter of the recesses 120, 220 is preferably within about 0.02-1.00 inch, or within about 0.02-0.15 inch, such as about 0.100 inch. Other recess 120, 220 diameters are possible, depending on the number of recesses and giving due consideration to the goal of permitting gas flow through said recesses. It will be understood that it is not necessary for all of the passages 116, 216 and recesses 120, 220 to have the same size or diameter.

In the embodiments described above, the recesses 120, 220 can be substantially evenly distributed throughout the respective central portions 102, 202. In other embodiments, these recesses can be unevenly distributed throughout the central portion 102, 202. The recesses 120, 220 can form any suitable pattern for delivering fluid, such as purge gas, cleaning gas, etc., through the central portion 102, 202. It is contemplated that the recesses 120, 220 can have any suitable size and configuration to achieve the desired fluid flow through the substrate holder 100, 200. The diameter of the recesses 120, 220 can be determined based upon empirical haze and resistivity results, as well as, for example, the desired flow rate of the gas passing through the central portion 102, 202. Additionally, the recesses 120, 220 can be similar to or different than one another, as desired.

The skilled artisan will appreciate that various arrangements of the thinned portions of the substrate holder 100 are possible and that the arrangement of the thinned portions is preferably optimized for strength as well as process control, for example, reducing haze/halo problem, resistivity, slip, nanotopography, etc. As mentioned above, cut-outs, for example in a honeycomb structure, in various shapes and sizes, rather than circular recesses may be provided to define the thinned portions of the substrate holder.

FIGS. 2A, 2B, 3A, and 3B make it clear that recesses 120, 220 can be provided on either the top surface 104, 204 or the bottom surface 106, 206 of the central portion 102, 202 of the substrate holder 100, 200. In some embodiments, one or more such recesses are provided in the top surface of the central portion 102, 202, and one or more additional recesses are provided in the bottom surface of the central portion 102, 202. Locating the cut-outs or recesses 220 on the bottom surface may be preferred (as in FIGS. 3A and 3B), because it reduces the risk of thermal imaging onto the substrate if the temperature of the substrate is not equal to the temperature of the substrate holder. In other words, the recesses or cut-outs 220 located on the bottom surface of the substrate holder are less likely to produce temperature non-uniformities than recesses or cut-outs 120 on the top surface of the substrate holder.

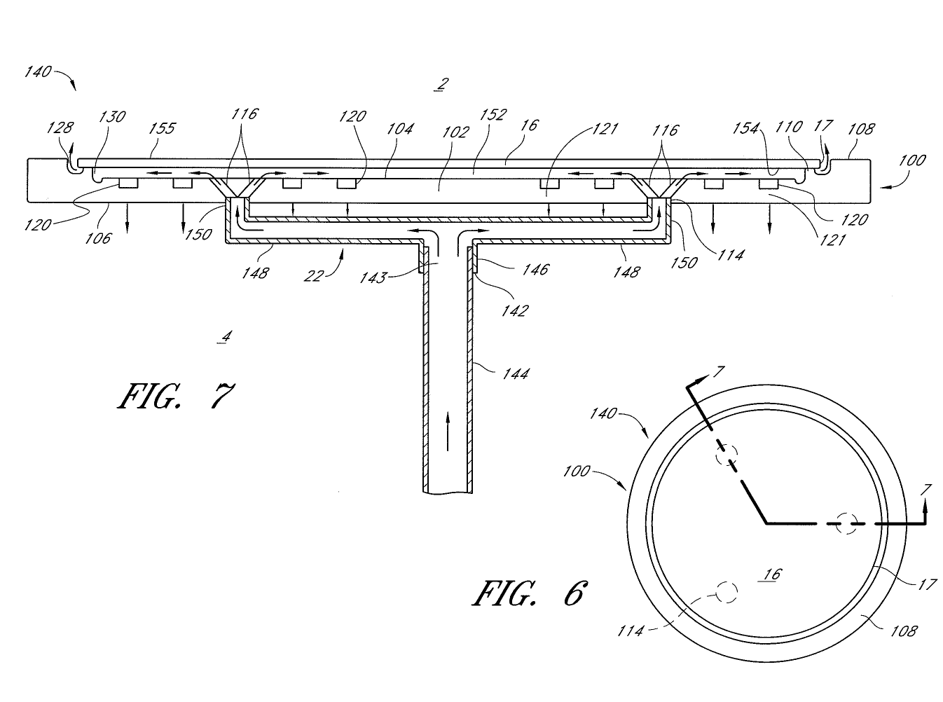

FIGS. 5A and 5B, which are a sectional view and an enlarged top view, respectively, of a peripheral portion of the substrate holder 100 of FIG. 2A, showing in greater detail the edge configuration of an embodiment of the substrate holder 100. The skilled artisan will appreciate that the embodiment of the substrate holder 200 shown in FIGS. 3A and 3B may have a similar peripheral portion. As mentioned above, the holder 100 includes an outer annular shoulder 108 outside of the spacer 110. The upper surface 132 of the shoulder 108 can be raised above the spacer 110, so that the shoulder 108 surrounds the peripheral edge 17 of a substrate 16 (FIGS. 1, 6, and 7), supported on the spacer 110.

In the embodiment illustrated in FIGS. 5A and 5B, the spacer 110 is surrounded by a shallow annular groove 128, which helps to minimize radiation losses from the substrate 16 to the substrate holder 100. The holder 100 also includes an annular thermal isolation groove 130 positioned radially inward from the spacer 110 and the shallow annular groove 128. The thermal isolation groove 130 helps to compensate for the heat conduction from the substrate 16 to the holder 100 in the area of the spacer 110, where the substrate 16 is supported by and in thermal contact with the holder 100.

FIGS. 6 and 7 illustrate a substrate support system 140 comprising the substrate holder 100 supported by a hollow support spider 22. FIG. 6 is a top plan view showing a substrate 16 supported by the substrate holder 100. In FIG. 6, the outlines of the support recesses 114 on the lower surface 106 are shown in dotted lines. FIG. 7 is a sectional view of the substrate support system 140 taken along lines 7-7 of FIG. 6. The support spider 22 includes a hollow body or manifold portion 146 having a lower inlet 142 engaged with an upper end or outlet 143 of a gas-conveyor 144 to facilitate gas flow from the gas-conveyor 144 into the manifold portion 146. The spider 22 can engage the gas-conveyor 144 in a fluid-tight manner, such as by employing a seal. In this embodiment, the gas-conveyor 144 comprises a rigid vertical tube, and the gas-conveyor 144 supports the spider 22. For example, the inlet 142 of the spider 22 can be configured to tightly secure onto the outlet 143 of the gas-conveyor 144, for example by threaded engagement. Alternatively, the manifold portion 146 can have an inner flange (not shown) that rests upon the upper end of the gas-conveyor 144. Still further, the manifold portion 146 can be sized such that it is inserted into the outlet 143 of the gas-conveyor 144. Skilled artisans will appreciate that there are a variety of configurations that will result in the gas-conveyor 144 supporting the spider 22, any of which can be applied to any of the embodiments described herein.

The spider 22 includes a plurality of hollow tubes or arms 148 extending generally radially outward and upward from the manifold portion 146, the arms 148 being configured to receive gas flow from the manifold portion 146. It will be appreciated that the tubes or arms 148 can have a variety of different cross-sectional shapes and sizes, including a cylindrical shape. Also, their cross-sectional shapes and sizes can vary along their length. The arms 148 have open upper ends 150 that support the lower surface 106 of the central portion 102 of the substrate holder 100.

In the illustrated embodiment, the upper ends 150 are received within the support recesses 114 of the holder 100. The upper ends 150 of the arms 148 can be configured to convey gas upwardly into the passages 116 within the support recesses 114 in a fluid-tight manner. It will be understood that the number of passages 116 into which the spider 22 delivers gas can be varied as desired. In some implementations, it may only be necessary to have one passage 116 that receives gas from the spider 22, in which case the spider may only include one hollow arm 148. The connection between the upper ends 150 of the arms 148 and the support recesses 114 also helps to transmit rotation of the spider 22 into rotation of the holder 100 and to prevent rotational slippage between the spider and the holder 100.

As shown in FIG. 7, the peripheral portion of a substrate 16 is supported on the upper support surface of the spacer 110. The spacer 110 is sized so that a thin gap region 152 exists between the upper surface 104 of the central portion 102 and a backside 154 of the substrate 16. The height of the gap region 152 is controlled by the height of the spacer 110. The gap region 152 can have a substantially uniform height. Alternatively, the height of the gap region 152 can vary if the upper surface 104 is not flat. For example, the upper surface 104 can be concave or may include protrusions or a grid structure with grooves. For simplicity of illustration, the arrangement and number of the recesses 120 in FIG. 7 is somewhat different than shown in FIGS. 2 and 3. Skilled artisans will appreciate that a large variety of different arrangements and numbers of recesses 120 is possible.

The substrate holder 100 and the support spider 22 can be made from different materials that have different coefficients of thermal expansion, such as silicon carbide and quartz. In one embodiment, the support recesses 114 are replaced with radial grooves that are identically sloped to promote a self-centering effect during differential thermal expansion between the holder 100 and spider 22. Further details of this self-centering structure are disclosed in U.S. Pat. No. 6,893,507.

The use of the substrate support system 140 for processing the substrate 16 is now described with respect to the embodiment of the substrate holder 100 shown in FIGS. 2A, 2B, and 7. The skilled artisan will understand that the embodiments of the substrate holders 200 shown in FIGS. 3A, 3B, and 4 may be used in a similar manner. According to an embodiment, the substrate 16 rests upon the substrate holder 100 so that the spacer 110 supports a peripheral portion of the substrate 16. A gas source is provided to inject a flow of inert gas, which is also known as “purge gas” or “sweep gas,” upwardly through the gas-conveyor 144. In FIG. 7, the flow of the inert gas is depicted by arrows. The inert gas flows into the manifold portion 146 of the support spider 22 and then into the hollow arms 148 of the spider 22. The inert gas continues upwardly through the passages 116 into the gap region 152 between the substrate 16 and the substrate holder 100. As shown, the passages 116 can be inclined so that the inert gas flow does not impinge upon the substrate 16 at a 90° angle. This incline helps to reduce the extent to which the inert gas flow may undesirably cool and create cold spots within the substrate 16. Upon emerging from the passages 116, the inert gas flows throughout the gap region 152. Some of the inert gas flows radially outwardly between the substrate 16 and the spacer 110, and upwardly around the peripheral edge 17 of the substrate 16 into the upper reactor chamber 2. The rest of the inert gas exits the gap region 152 by flowing downward through the recesses 120 and downward through the porous material of the substrate holder 100 in the thinned portions 121 and into the lower reactor chamber 4. It is of course possible that some gas may flow through the thicker portions of the porous substrate holder. However, most of the gas will tend to flow through the thinned portions 121, which offer relatively less flow resistance.

Optionally, a second flow of gas, such as an inert gas, can be directed into the lower chamber 4 generally underneath and parallel to the lower surface 106 of the central portion 102 of the substrate holder 100, to sweep away the inert gas emerging downward from the thinned portions 121 of the substrate holder under the lower ends of the recesses 120. A separate downstream reactor outlet or exhaust can be provided in the chamber 4 underneath the quartz chamber dividers 36, which are shown in FIG. 1, for the removal of these mixed gas flows.

Simultaneously with the above-described flow of inert gas, reactive process gases are directed generally horizontally above the substrate 16 in the upper reactor chamber 2. In other words, the reactive process gas flow and the inert (or cleaning) gas flow can overlap in time. The flow of reactive gases results in the deposition of processing materials onto the front side 155 of the substrate 16. The upward flow of inert gas around the edge 17 of the substrate 16 substantially reduces, inhibits, or prevents the downward flow of reactant gas around the substrate edge 17 and into the gap region 152. Thus, the inert gas substantially reduces, inhibits, or prevents deposition of the process gases on the substrate backside 154. In addition, the support spider 22, the substrate holder 100, and the substrate 16 can be rotated about a central vertical axis during processing. Typically, the gas-conveying tube 144 is rotatable and transmits its rotation to the spider 22, the substrate holder 100, and the substrate 16. In particular, the inlet 142 of the spider 22 (or other embodiments of hollow support members, described below) can be configured to engage the outlet 143 of the gas-conveyor 144 such that rotation of the gas-conveyor 144 about a vertical axis causes the spider 22 (or other hollow support member) and substrate holder 100 to rotate with the gas-conveyor 144.

It will be understood that the substrate support system 140 also reduces autodoping. As diffused dopant atoms emerge from the backside 154 of the substrate 16, the controlled flow of inert gas within the gap region 152 forces most of the dopant atoms downward through the recesses 120 and the porous material of the substrate holder 100 in the thinned portions 121 and into the lower reactor chamber 4. Thus, the diffused dopant atoms are redirected and do not flow upwardly around the substrate edge 17 into the upper reactor chamber 2 to re-deposit on the front side 155 of the substrate 16. Also, if some out-diffused dopant atoms happen to flow radially outward between the spacer 110 and the substrate 16, the momentum of the inert gas flowing upward around the substrate edge 17 can send such dopant atoms higher and away from the substrate front side 155, to be carried away by the general flow of reactant gases and deposition by-products in the upper reactor chamber 2. This upward flow of dopant atoms can be additionally controlled by changing the ratio of gas flows in chambers 2 and 4.

The skilled artisan will appreciate that the hollow support spider 22 permits a controllable, direct forced flow of inert gas into the gap region 152. Based upon the specific design of the substrate holder 100 and spider 22, inert gas can be delivered directly into any number of selected passages 116 at desired locations within the central portion 102 of the holder 100. This substrate support system 140 more effectively reduces or prevents backside deposition and autodoping.

With reference to FIG. 1, as mentioned above, the dividers 36 of the reactor 10 do not always completely prevent the flow of reactant gases from the upper reactor chamber 2 into the lower chamber 4. In some prior art systems, such reactant gases below the substrate holder can flow to the substrate backside and deposit thereon. The substrate support system 140 shown in FIGS. 6 and 7 solves this problem. The forced flow of inert gas into the support spider 22 and through the passages 116 causes a pressure bias that results in downward flow of inert gas through the substrate holder 100, via the recesses 120, which, along with heightened pressure in the gap region 152, reduces the upward flow of reactant gases through the substrate holder 100 to the substrate backside 154. The pressure in the gap region 152 is desirably higher than in the lower chamber 4 of the reactor. The risk of backside deposition can also be reduced by maintaining a pressure differential between the upper and lower chambers 2 and 4, wherein the pressure in the lower chamber 4 is kept higher than the pressure in the upper chamber 2. This pressure differential can be produced by introducing some inert gas directly into the lower chamber 4 and reducing the size of any escape paths from the chamber 4. This extra inert gas can be introduced into the chamber 4 by providing an alternative flow path from the gas-conveyor 144 to the chamber 4, for example, a flow path through which the inert gas can flow into the chamber 4 without flowing through the gap region 152, or an entirely separate gas inlet.

It will also be understood that the substrate support system 140 can be used to remove the native oxide layer from the backside 154 of the substrate 16. Cleaning gas, such as H₂ gas, can be delivered upwardly through the gas-conveyor 144 and spider 22, into the gap region 152. At a high enough temperature, the cleaning gas removes the oxide layer from the backside 154. The excess cleaning gas and oxide removal by-products then flow out of the gap region 152 through the recesses 120 and through the porous material of the holder 100 in the thinned portions 121 under the recesses 120, and, to some extent, upwardly around the peripheral edge 17 of the substrate 16. Oxide layer removal can be conducted simultaneously for the backside 154 and front side 155 of the substrate 16. Thus, the substrate backside cleaning operation may involve the simultaneous introduction of a generally horizontal flow of cleaning gas above the substrate 16 in the upper reactor chamber 2. The spider 22, the holder 100, and the substrate 16 can be rotated about the central vertical axis during the cleaning operation. The skilled artisan will appreciate that such rotation improves uniformity and thoroughness of the oxide layer removal. It has been found that, in some embodiments, nearly complete removal of the oxide layer from the substrate backside 154 can be achieved with a “bake.” For example, a “bake” may comprise an exposure of the backside 154 to the cleaning gas at a sufficiently high temperature, such as a temperature greater than 1100° C., for less than two minutes, and, in some cases, between 40 and 60 seconds, depending on the temperature. It will be understood that the required duration of the bake decreases as temperature increases.

Skilled artisans will appreciate that other substrate holders can be used in place of the holders 100, 200 described herein, particularly those that provide a gap region 152 between the backside of the substrate 16 and an upper surface of the holder. For example, a substrate holder having a different type of spacer element, such as spacer lip portions, spacer nubs or pins fixed to the upper surface, an annular lip with a few gas flow grooves, etc., can be used.

The substrate holders 100, 200 comprise an improvement over prior art substrate holders that include open passages that extend between the top and bottom surfaces of the substrate holder. Such open passages can result in nanotopography defects and crystallographic slip problems. Such open passages can allow light to pass through the substrate holder, which can result in hotspots across the surface of a supported substrate if the substrate holder is not formed of a light-transmissive material. This can frustrate the goal of achieving temperature uniformity across the substrate. In contrast, the substrate holders 100, 200 of the present application do not include any open passages that allow a direct line of sight through the central portion 102 of the substrate holder. Thus, if the substrate holder 100, 200 is formed of a material that blocks light, the light cannot pass through the substrate holder. On the other hand, if the substrate holder 100, 200 is formed of a light-transmissive material, such as quartz, then there such hotspots are not produced.

Another advantage of the substrate holders of the present application over prior art substrate holders that include open passages that extend to the top and bottom surfaces of the substrate holder relates to the specific heat capacity of the holder. The substrate holders of the present application include thin porous portions through which gas flows, as well as thicker portions. The thicker portions provide structural rigidity to the substrate holder. The thin portions can comprise a large portion of the central portion 102, 202 of the substrate holder 100, 200, which can significantly reduce the specific heat capacity of the holder. This allows the substrate holder to be heated and cooled more quickly, which improves substrate throughput. In certain embodiments, the thinned portions 121 (or the thinned portions of other embodiments) comprise at least about 10%, or at least about 20%, of the upper or lower surface of the central portion of the substrate holder. In certain embodiments, the thinned portions comprise about 20%-80% of the upper or lower surface of the central portion of the substrate holder.

In the illustrated embodiments, the passages 116, 216 are completely open. In alternative embodiments, the passages 116, 216 are replaced by thinned portions of the porous substrate holder, such that the upwardly flowing gas has to flow through the porous substrate holder to reach the gap region 152. Such alternative embodiments might be preferred because they reduce the risk of substrate lift (discussed below) by impeding the upward flow of inert gas through the substrate holder.

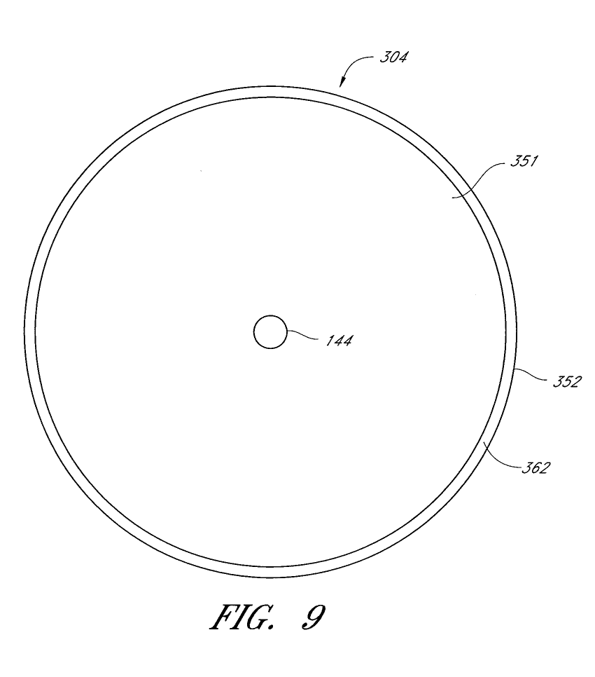

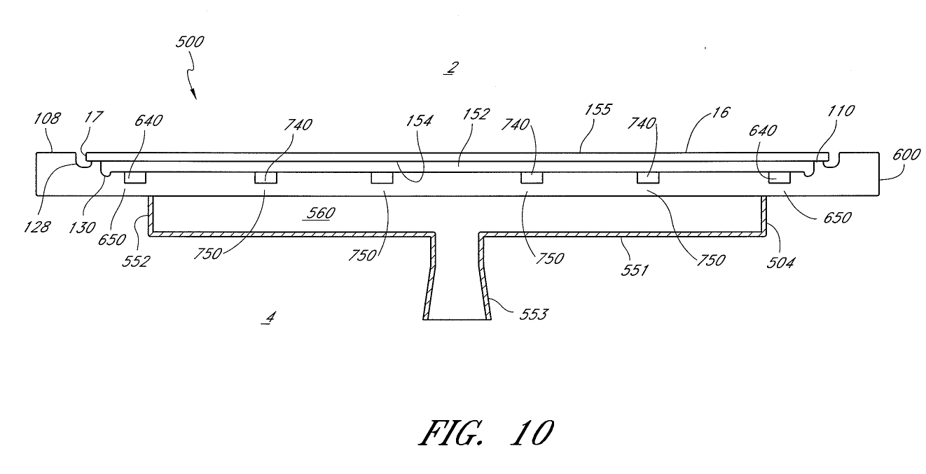

FIGS. 8 and 9 illustrate a substrate support system 300 according to another embodiment. The support system 300 includes a generally bowl- or cup-shaped substrate holder support 304 in place of a support spider. FIG. 8 is a side sectional view of the entire system 300, while FIG. 9 is a top plan view of the holder support 304 alone. The system 300 can support a substrate 16 during substrate processing, for example, CVD such as epitaxial deposition, or oxide layer removal. Like the above-described system 140, this system 300 prevents or reduces the extent to which process gases contact the backside 154 of the supported substrate 16. The system 300 also reduces or prevents autodoping. Similar to a support spider, the substrate holder support 304 may be mounted to a gas-conveyor 144, such as a rotatable vertical tube, and can also engage and support the substrate holder 100. The substrate holder support 304 can rotatably couple the substrate holder 400 to a tube 144, such that the tube 144, holder support 304, and substrate holder 400 rotate in unison.

In the illustrated embodiment, the substrate holder support 304 includes a generally flat base 351 that extends from the upper end of the gas-conveying tube 144 to a generally vertical end structure 352 that can be annular. In an embodiment, the structure 352 comprises a wall. The substrate holder 400 can rest, preferably stably, on an upper edge 362 of the vertical wall 352. The upper edge 362 can be configured to restrict fluid flow across an interface between the upper edge 362 and the lower surface 406 of the holder 400. In this embodiment, the wall 352 defines a relatively large upper opening of the holder support 304, which upper opening underlies at least a majority portion of the lower surface 406 of the substrate holder 400. This upper opening defines an area whose size is a certain percentage of the size of a substrate 16 that the substrate holder 100 is specifically designed to support. According to an embodiment, this percentage is between 50-120%. According to other embodiments, this percentage is between 70-120%, 95-120%, 50-100%, or 70-100%.

A chamber 360 is defined between an upper surface 365 of the base 351 and the lower surface 406 of the central portion 402 of the holder 400. In this embodiment, the recesses 440 and the porous material of the substrate holder 400 in the thinned portions 441 under the recesses 440 provide fluid communication between the gap region 152 and the chamber 360 defined between the holder 400 and the holder support 304. The skilled artisan will appreciate that the holder support 304 can be constructed from materials with suitable characteristics, such as quartz, graphite coated with silicon carbide, or other materials so long as the shading or blocking of radiation by the material is taken into account. For example, light can pass through quartz, but not through graphite coated with silicon carbide, and the latter is more likely to produce temperature variations across the substrate. One of ordinary skill in the art can determine the appropriate combination of material type, thickness, and shape of the holder support 304.

In the embodiment illustrated in FIGS. 8 and 9, the substrate holder 400 is substantially the same as the substrate holder 100 shown in FIGS. 2-7. However, skilled artisans will appreciate that other substrate holders can be used, particularly those that provide a gap region between the backside of the substrate 16 and an upper surface of the substrate holder. For example, a substrate holder having a different type of spacer element, such as spacer lip portions, spacer nubs or pins fixed to the holder surface, an annular lip with a few gas flow grooves, etc., can be used. Skilled artisans will also understand that, for the purposes of this embodiment, the support recesses 114 of the holder 100 can be modified or omitted, as there are no spider arms to engage them. The holder 400 illustrated in FIGS. 8 and 9 includes recesses 440 having upper ends 442 at the upper surface 404 of the substrate holder 400. The skilled artisan will appreciate that, in an alternative embodiment, the recesses 440 may be provided on the lower surface 406 of the substrate holder 400.

The substrate holder 400 can be removably or permanently coupled to the substrate holder support 304 which, in turn, is connected to the gas-conveyor 144. In certain embodiments, the substrate holder 400, the substrate holder support 304, and the gas-conveyor 144 are formed integrally from the same material. In some embodiments, the substrate holder 400 and substrate holder support 304 are formed integrally, while the gas-conveyor 144 is formed separately. In some embodiments, the gas-conveyor 144 and substrate holder support 304 are formed integrally, while the substrate holder 400 is formed separately. Finally, in some embodiments all three of such elements are formed separately. The substrate holder 400 can be stably supported by the substrate holder support 304 so that they rotate in unison substantially without slippage therebetween. For example, the substrate holder 400 can rest upon the substrate holder support 304, so that the substrate holder 400 can be conveniently lifted off of the substrate holder support 304. In other embodiments, the bottom surface 406 of the substrate holder 400 is configured to interlock, for example, via a groove in the substrate holder, snap-connection, pin/hole interlock, or other suitable means, with an upper edge or surface of the holder support 304 to rotationally lock the substrate holder 400 with the holder support 304.

As shown in FIG. 8, the illustrated substrate holder support 304 comprises a base 351 and an annular vertical wall 352. The base 351 extends from the wall 352 to a flange 353 that engages the gas-conveyor 144. In the illustrated embodiment, the base 351 extends horizontally from the flange 353 and has a shape that is generally similar to the shape of the substrate holder 400. However, the base 351 can have any shape suitable for having a portion of the holder support 304, such as the wall 352, engage the lower surface 406 of the substrate holder 400. The wall 352 of the substrate holder support 304 extends upwardly from the periphery of the base 351. The wall 352 is sized and configured such that it can hold and support the substrate holder 400 with the substrate 16 supported thereon. In the illustrated embodiment, the wall 352 is generally vertically oriented and perpendicular to the base 351. Although not illustrated, the wall 352 can be oriented at any angle with respect to the base 351 and the substrate holder 400 can be frusto-conical, depending on, for example, the desired distance between the base 351 and the lower surface 406 of the substrate holder 400. Additionally, the wall 352 can have any height to achieve the desired distance between the base 351 and the substrate holder support 304.

In the illustrated embodiment, the chamber 360 is generally cylindrical. In one embodiment, the chamber 360 has a generally constant height. In another embodiment, the height of the chamber 360 varies in the radial direction. For example, the height of the chamber 360 can decrease in the radially outward direction. However, the chamber 360 can have any desired and suitable height profile. In the illustrated embodiment, the base 351 and wall 352 form a generally U-shaped cross sectional profile. This profile can alternatively be V-shaped, W-shaped, semicircular, combinations thereof, or any other suitable shape.

The size and configuration of the base 351 and wall 352 can be varied in order to obtain a desired size and configuration of the chamber 360. In the illustrated embodiment, for example, the substrate holder support 304 is generally bowl- or cup-shaped such that the chamber 360 is generally cylindrical with a substantially uniform height equal to the height of the wall 352. The diameter of the base 351 can be selected depending on the desired location of the edge or upper portion 362 of the wall 352. In the illustrated embodiment shown in FIGS. 8 and 9, the base 351 is sized so that the wall 352 is located radially outward of all of the recesses 440 of the substrate holder 400.

The substrate holder support 304 (FIGS. 8 and 9) can be mounted to the upper end or outlet 143 of the gas-conveyor 144. In one embodiment, the gas-conveyor 144 is a hollow tubular member that provides fluid, such as cleaning gas and/or inert gas, to the substrate holder support 304. The tube 144 includes a tube passage 310 that extends through the tube 144 to the chamber 360. The gas-conveyor 144 can be rotated to simultaneously rotate the holder support 304, the substrate holder 400, and the substrate 16. Optionally, the gas-conveyor 144 can be moved in a vertical direction to move the substrate holder 400, the holder support 304, and the substrate 16 upwardly and/or downwardly. It will be understood that the gas-conveyor 144 can move the substrate holder 400 and the holder support 304 when the substrate 16 is not loaded onto the substrate support system 300.

In the illustrated embodiment of FIGS. 8 and 9, the relatively small recesses 440, each having a diameter within a range of, for example, about 0.5-3.0 mm, and the porous material of the substrate holder 400 in the thinned portions 441 permit fluid communication between the gap region 152 and the chamber 360. Gas can migrate between the gap region 152 and the chamber 360 via the recesses 440 and through the porous material of the substrate holder 400 in the thinned portions 441 under the recesses 440. In other embodiments, such fluid communication can be effected by thinned portions of the substrate holder 440 under or over cut-outs of various shapes and sizes in the central portion 402 of the holder 400. The recesses 400 may be on either the top side or bottom side of the substrate holder 400, although the recesses 440 are desirably on the bottom side of the substrate holder 400 to prevent thermal imaging (variations in substrate temperature caused by the substrate holder) if the temperature of the substrate holder 400 is different from the temperature of the substrate.

The substrate holder 400 and the substrate holder support 304 can be made from materials that have similar or different coefficients of thermal expansion. In one embodiment, the holder 400 and the holder support 304 have similar coefficients of thermal expansion to reduce relative movement between the lower surface 406 of the holder 400 and the upper portion 362 of the wall 352.

In one embodiment, frictional engagement between the upper portion 362 of the wall 352 of the holder support 304 and the lower surface 406 of the substrate holder 400 maintains the position of holder 400 relative to the holder support 304. The holder 400 can be centered about the axis of rotation of the gas-conveyor 144. Optionally, the holder 400 can have a means for centering itself relative to the holder support 304. For example, the lower surface 406 can have ridges or grooves configured to engage with the upper portion 362 to ensure that the holder 400 remains in or moves to a desired position relative to the holder support 304. At least one of the upper portion 362 and lower surface 406 can have protuberances, splines, grooves, roughened surfaces, or other surface features for preventing slippage between the holder 400 and the holder support 304, particularly during rotation of the holder 400 and holder support 304. Optionally, a seal can be formed between the upper portion 362 and the lower surface 406 of the holder 400 to maintain the integrity of the chamber 360. For example, the seal can inhibit or prevent processing gases in the lower reactor chamber 4 from entering into the chamber 360.

In the illustrated embodiment, the substrate holder 400, substrate holder support 304, and gas-conveyor 144 are configured to inhibit backside deposition. During substrate processing, an inert gas is directed upward through the gas-conveyor 144 into the chamber 360. The inert gas flows throughout and fills the chamber 360. Some of the inert gas flows into the porous material of the substrate holder 400. Some of the inert gas flowing through the porous material, especially in the thinned portions 441 under the recesses 440, flows through the recesses 440 and into the gap region 152. The inert gas within the gap region 152 forms a “gas curtain” that inhibits or prevents process gases in the upper reactor chamber 2 above the substrate 16 from effusing around the substrate edge 17 to the gap region 152. Specifically, the inert gas within the gap region 152, due to an at least slightly elevated pressure compared to the process gas pressure in the chamber 2 above the substrate 16, tends to flow upwardly between the substrate holder 400 and the substrate 16 around the substrate edge 17. In the illustrated embodiment, the inert gas exits the gap region 152 by flowing radially outward between the spacer 110 and the substrate 16, and then upward around the substrate edge 17, as described above in connection with the embodiment of FIGS. 2-7.

If the pressure within the gap region 152 is too high, the substrate 16 may undesirably lift and/or slide with respect to the substrate holder 400. If the pressure within the gap region 152 is too low, reactant gases above the substrate 16 may effuse around the substrate edge 17 into the gap region 152. The pressure of the inert gas within the gap region 152 can be either slightly or substantially greater than the pressure of the reactant gases within the upper reactor chamber 2, but not so great as to cause the substrate 16 to lift and/or slide with respect to the substrate holder 400. In selecting the gas pressure inside the gap region 152, the goal is to substantially prevent or reduce the flow of reactant gas from the chamber 2 around the substrate edge 17 into the gap region 152, without introducing a substantial risk of substrate cooling, localized or otherwise, or substrate lift or slide. Skilled artisans will be able to determine the appropriate gas pressure within the gap region 152 based upon these considerations. In one embodiment, it is contemplated that the inert gas flowing into the chamber 360 will ordinarily be provided at a relatively low flow rate of 0.4-3.0 slm, with 2.0-3.0 slm being typical. In some embodiments, some of the gas flowing through the gas-conveyor 144 is diverted for other purposes, such as purging a ferrofluidic seal or purging thermocouples. In an implementation, little or no reactant gas within the chamber 2 flows into the gap region 152 during substrate processing.

In comparison to the gas-conveying spider 22 discussed above, which directs the inert gas directly into the passages 116, which are shown in FIGS. 2 and 3, of the substrate holder 100, the substrate holder support 304 reduces localized cooling of the substrate 16. This reduction is achieved because the holder support 304 does not direct jets of the inert gas directly onto specific locations of the substrate backside 154. In contrast, the gas-conveying spider 22 can produce such localized cooling if open passages 116 are provided instead of thinned porous portions 441 of the substrate holder. The holder support 304 tends to permit the inert gas to migrate more slowly through the porous material of the holder 400 and the recesses 440, such that the gas does not impinge the substrate backside 154 with as much momentum.

With reference to FIG. 1, as mentioned above the dividers 36 of the reactor 10 do not always completely prevent the flow of reactant gases from the upper reactor chamber 2 into the lower chamber 4. In some prior art systems, such reactant gases below the substrate holder can flow to the substrate backside and deposit thereon. The substrate support system 300 shown in FIG. 8 and 9 solves this problem. The substrate holder support 304 substantially inhibits or prevents such reactant gases in the chamber 4 from passing through the porous holder 400 and the recesses 440 into the gap region 152. In particular, the base 351 and annular wall 352 inhibit the flow of these reactant gases into the chamber 360. Optionally, the inert gas in the chamber 360 can be pressurized sufficiently to prevent or inhibit reactant gases within the lower chamber 4 from effusing between the upper portion 362 of the wall 352 and the lower surface 406 of the substrate holder 400 and into the chamber 360. For example, the inert gas pressure in the chamber 360 can be maintained at least equal to or slightly higher than the gas pressure in the lower chamber 4. Also, the system 300 can alternatively be used in a reactor 10 that does not have dividers 36 separating the upper and lower chambers 2 and 4. Omitting the dividers 36 can reduce cost and complexity and can avoid some processing problems, such as devitrification and unwanted coating on the quartz dividers 36.

The substrate support system 300 of FIGS. 8 and 9 also facilitates the removal of a native oxide layer from the substrate backside 154. The oxide layer can be removed from the substrate backside 154 by injecting a cleaning gas, such as H₂, upward through the gas-conveyor 144. Excess cleaning gas and oxide removal byproducts can exit the system 300 by flowing upward around the substrate edge 17 into the upper reactor chamber 2. Rotation of the substrate holder 400 can assist in such flow of the cleaning gas and oxide removal byproducts. Typically, additional cleaning gas is concurrently provided above the substrate 16 in the upper chamber 2 to simultaneously remove an oxide layer from the front side 155 of the substrate 16.

With continued reference to FIGS. 8 and 9, the inert gas flowing through the substrate support system 300 can be silicon-free inert gas, such as hydrogen gas. It will be understood that hydrogen gas can act as an inert purge or sweep gas as well as a cleaning gas. When there is no oxide layer on a silicon wafer 16, and under certain temperature conditions, the hydrogen gas is inert. When there is an oxide layer of SiO₂ on the silicon wafer 16, the hydrogen gas can chemically reduce the oxide layer to remove the oxygen and leave exposed silicon on the wafer surface. In one embodiment, the inert gas is almost entirely hydrogen. However, other gas or gases can flow through the substrate support system 300.

With continued reference to FIGS. 8 and 9, the pressure and flow rate of gas flowing through the gas-conveyor 144 into the chamber 360 and the gap region 152 can be adjusted based on the size and configuration of the substrate 16, the substrate holder 400, and the holder support 304. The pressure and flow rate of the gas can also be adjusted based upon the flow parameters and characteristics of gas within the lower reactor chamber 4.

In the illustrated embodiment, the pathways 440 upward gas flow through the substrate holder 400 comprise recesses 440 with thin porous portions of the holder 400. In an alternative embodiment, some or all of the recesses 440 are replaced with open passages. While recesses reduce the risk of substrate lift by impeding the upward flow of inert gas through the substrate holder, open passages allow the inert gas to flow more readily into the gap region 152. Skilled artisans will appreciate that the choice of whether to replace any of the recesses 440 with open passages, and how many should be so replaced, requires a balancing of the goal of allowing the inert gas to flow freely into the gap region 152 against the goal of preventing substrate lift.

FIG. 10 illustrates a substrate support system 500 according to another embodiment. Many of the components of the system 500 are similar to the substrate support system 300 described above and will therefore not be discussed in detail. As discussed below, the substrate support system 500 very effectively reduces autodoping while still significantly preventing or reducing the extent of substrate backside deposition.

With continued reference to FIG. 10, the substrate support system 500 includes a substrate holder support 504 sized and configured to support the substrate holder 600. As described above, the holder support 504 includes a flange 553 configured to attach to an upper end or inlet of a gas-conveyor, such as a rotatable vertical tube. In the substrate support system 500, at least one recess 640 and thinned portion 650 of the porous material of the substrate holder 600 is located radially outward of the annular wall 552 of the holder support 504. Gas emerging downwardly from the one or more thinned portions 650 flows into the lower chamber 4 of the reactor and does not flow into the chamber 560. In one embodiment, a plurality of such recesses 640 and thinned portions 650 is arranged substantially along a circle on the upper or lower surfaces of the substrate holder 600, preferably near the edge of the substrate 16, such that gas emerging from this “ring” of thinned portions 650 does not flow into the chamber 560. As used herein, a “ring” of recesses and thinned portions refers to a plurality of recesses and so-defined thinned portions arranged substantially along a circle on the substrate holder. In another embodiment, multiple concentric rings of recesses 640 and thinned portions 650 may be located radially outward of the annular wall 552. At least one outermost ring of recesses 640 and thinned portions 650 can be positioned at substantially even angles with respect to the circumference of the substrate holder 600. During substrate processing, inert gas flowing downward through the at least one outermost ring of recesses 640, and through the thinned portions 650 of the porous substrate holder 600 underneath said recesses 640, sweeps most or substantially all of the diffused dopant atoms out of the gap region 152 and into the reactor lower chamber 4 below the substrate holder 600, as discussed below. The recesses 640 located radially outward of the substrate holder support 504 can alternatively be unevenly spaced about the periphery of the base plate 551.

In the following description, referring still to FIG. 10, the reference numeral 740 refers to recesses positioned such that gas emerging from the thinned portions 750 formed by these recesses 740 is discharged into the chamber 560 of the holder support 504, and the reference numeral 640 refers to recesses located so as to discharge gas through the porous thinned portions 650 to the chamber 4 outside of the holder support 504.

In operation, an inert gas can be fed through a gas-conveyor into the flange inlet 553. The inert gas flows upwardly into the chamber 560 defined between the substrate holder support 504 and the substrate holder 600. The inert gas then flows through the porous material of the thinned portions 750 of the substrate holder 600 and through the recesses 740 into the gap region 152 above the substrate holder 600. The inert gas can flow throughout and substantially fill the gap region 152. A substantial portion of the inert gas in the gap region 152 flows downwardly through the recesses 640 and the porous thinned portions 650 into the lower reactor chamber 4. Thus, the gap region 152 is in fluid communication with both the chamber 4 and the chamber 560. The number, depth, and locations of the recesses 640 can be determined based on the desired flow parameters of the inert gas within the gap region 152 and/or the chamber 4. Advantageously, dopant atoms that diffuse through the substrate 16 and emerge from the substrate backside 154 are substantially swept out of the gap region 152 by the flow of inert gas downward through the recesses 640 and the porous thinned portions 650 into the chamber 4. This sweeping substantially prevents or reduces the amount of autodoping on the upper surface of the substrate 16. The inert gas pressure within the gap region 152 can be slightly or substantially higher than the pressure within the chamber 4, such pressure differential creating a forced flow of inert gas through the recesses 640 and the porous thinned portions 650 into the chamber 4. In an implementation, little or no gas within the chamber 4 passes through the recesses 640 and the porous holder 600 into the gap region 152.

With continued reference to FIG. 10, some of the inert gas in the gap region 152 may flow radially outward between the spacer 110 and the supported substrate 16, and upwardly around the substrate edge 17. This portion of the inert gas may sweep some of the diffused dopant atoms upward into the upper reactor chamber 2, which introduces a risk of autodoping. This autodoping risk can be reduced by adjusting the size of the recesses 640 and the thickness of the porous thinned portions 650 formed by the recesses 640. In other words, these dimensions can be varied so that the inert gas is more likely to exit the gap region 152 through the recesses 640 and thinned portions 650 rather than through the interface between the spacer 110 and the supported substrate 16.

As mentioned above, the annular spacer 110 can be replaced by a ring of spacer veins. In choosing between these two options, skilled artisans can balance the need for reduced autodoping against the need for temperature uniformity in the wafer. A solid holder ledge provides greater resistance against autodoping because it blocks the flow of dopant atoms that would otherwise effuse around the substrate edge 17. Spacer veins minimize heat conduction between the substrate holder and the substrate 16, thus improving temperature uniformity, particularly with respect to dynamic uniformity and crystallographic slip within the substrate. It should be noted that even when veins are used, autodoping can be suitably reduced by increasing the forced flow rate of inert gas through the system. It will also be appreciated that a solid substrate holder ledge can better inhibit backside deposition.

With continued reference to FIG. 10, the risk of autodoping can also be reduced by suitably controlling the pressures in the regions 152, 2, and 4. The inert gas pressure in the gap region 152 is greater than the pressures in the upper reactor chamber 2 and lower reactor chamber 4. If it were not, the inert gas would not flow into the chambers 2 and 4. Optionally, the pressure in the upper chamber 2 can be maintained slightly or substantially higher than the pressure in the lower chamber 4, so that the inert gas in the gap region 152 prefers flowing through the recesses 640 rather than through the interface between the spacer 110 and the supported substrate 16.

Of course, the objective of having most of the inert gas exit the gap region through the recesses 640 is suitably balanced against the possible objective of having some of the inert gas flow radially outward between the spacer 110 and the supported substrate 16 to prevent backside deposition of reactant gases from the upper chamber 2. In adjusting the size and depth of the recesses 640 and the pressures of the regions 152, 2, and 4, skilled artisans will be able to suitably balance these goals in implementing the substrate support system 500.

The substrate support system 500 of FIG. 10 can also substantially prevent backside deposition by sweeping reactant gases downward through the recesses 640. Reactant gases from the upper reactor chamber 2 may effuse downward between the substrate edge 17 and the shoulder 108 of the substrate holder 600, particularly if the inert gas in the gap region 152 does not flow radially outward between the spacer 110 and substrate 16. If such reactant gases flow radially inward through the interface between the spacer 110 and the substrate 16, the forced flow of inert gas sweeps substantially all of the reactant gas downward through the recesses 640 into the lower reactor chamber 4. In this manner, the system 500 substantially prevents or reduces the extent to which the effused reactant gases may deposit on the backside 154 of the substrate 16. At least one ring of recesses 640 and thinned portions 650 can be positioned very close to the thermal isolation groove 130 to minimize the peripheral area of the substrate backside 154 on which the reactant gases may become deposited. An outermost ring of recesses 640 and thinned portions 650 can be positioned such that any backside-deposited reactant gases deposit only within the exclusion zone of the substrate 16.

In one embodiment, the substrate support system 500 is configured so that there is only one recess 640 positioned so that gas emerging downwardly from the porous thinned portion 650 underneath the recess 640 flows into the lower reactor chamber 4 outside of the substrate holder support 504. In an implementation, the inert gas flowing downward through such a single recess 640 sweeps most or substantially all of the out-diffused dopant atoms out of the gap region 152 to the lower chamber 4. Since this is achieved by providing one recess 640 outside the annular wall 552 in the system 500, it may be desirable to inject the inert gas into the holder support 504 at a more elevated pressure, compared to the inert gas pressure of the system 300 shown in FIGS. 8 and 9, in order to more effectively sweep dopant atoms and/or downwardly effused reactant gases into the single recess 640 and through the porous thinned portion 650. It may also be desirable to increase the size of the single recess 640 to some degree. This embodiment with only one recess 640 results in greater inert gas flow upwardly around the substrate edge 17, thereby more effectively preventing or reducing backside deposition of reactant gases. It will be understood that the flow of the inert gas is preferably limited to avoid lifting the substrate off of the substrate holder.

It will be understood that the substrate support system 500 can also be used to remove an oxide layer from the substrate backside 154 by injecting a cleaning gas upward into the flange inlet 553 of the substrate holder support 504. The cleaning gas flows upward through the chamber 560 and porous thinned portions 750 and into the recesses 740 to remove the oxide layer from the backside 154. The excess cleaning gas and oxide removal by-products exit the system 500 by flowing downward through the recesses 640 and porous thinned portions 650 and into the lower chamber 4 and/or radially outward between the spacer 110 and the supported substrate 16 into the upper chamber 2. A cleaning gas can also simultaneously be introduced into the chamber 2 to remove an oxide layer from the front side 155 of the substrate 16.

In the illustrated embodiment, the pathways for upward gas flow through the substrate holder 600 comprise recesses 740 with thin porous portions of the holder 400. In an alternative embodiment, some or all of the recesses 740 are replaced with open passages. While recesses reduce the risk of substrate lift by impeding the upward flow of inert gas through the substrate holder, open passages allow the inert gas to flow more readily into the gap region 152. Skilled artisans will appreciate that the choice of whether to replace any of the recesses 740 with open passages, and how many should be so replaced, requires a balancing of the goal of allowing the inert gas to flow freely into the gap region 152 against the goals of preventing substrate lift and, if a transparent substrate holder support 504 is used, preventing direct exposure the substrate backside 154 to light radiation.

With regard to the above-described embodiments 300 (FIGS. 8 and 9) and 500 (FIG. 10), the substrate holder support 304, 504 can be configured to convey gas upward through any number of recesses 440, 740 (and their associated thin porous portions) within the substrate holder. In an embodiment, this number of recesses is at least 9, but in other embodiments it can also be within 9-250, 6-225, 20-250, 50-200, 100-200, or 100-250. In the embodiment 100 (FIGS. 6 and 7), there is one recess 120 for each gas inlet from a spider 22. In other embodiments, one to six recesses 120 may be provided for each arm 148 of the spider 22, for a total of 3-18 recesses 120.

The methods described and illustrated herein are not limited to the exact sequences of steps described. Nor are they necessarily limited to the practice of all the steps set forth. Other sequences of steps or events, or less than all of the steps, or simultaneous occurrences of the steps, may be utilized in practicing the embodiments and methods of the invention.

Furthermore, the skilled artisan will recognize the interchangeability of various features from different embodiments. Similarly, the various features and steps discussed above, as well as other known equivalents for each such feature or step, can be mixed and matched by one of ordinary skill in this art to perform methods in accordance with principles described herein.

Although this invention has been disclosed in the context of certain embodiments and examples, it will be understood by those skilled in the art that the present invention extends beyond the specifically disclosed embodiments to other alternative embodiments and/or uses of the invention and obvious modification thereof. Thus, it is intended that the scope of the present invention herein disclosed should not be limited by the particular disclosed embodiments described above, but should be determined only by a fair reading of the claims that follow.

What is claimed is:

1. A substrate support system comprising a substrate holder for supporting a substrate, the substrate holder comprising a central portion such that the substrate is spaced apart from the central portion when the substrate is supported by the substrate holder, the central portion having one or more recesses defining thinned portions of the central portion, the central portion being formed of a material having a porosity between about 10%-40% and configured to allow gas flow therethrough.

2. The substrate support system of claim 1, further comprising a hollow support member having an inlet adapted to engage an outlet of a gas-conveyor to facilitate gas flow from the gas-conveyor into the hollow support member, the hollow support member having one or more upper open ends adapted to support the lower surface of the central portion of the substrate holder, the one or more upper open ends configured to convey gas upwardly through the central portion of the substrate holder.

3. The substrate support system of claim 2, wherein the one or more upper open ends are configured to convey gas upwardly into the recesses and the one or more thinned portions.

4. The substrate support system of claim 2, wherein the central portion further comprises a plurality of passages extending from the upper surface of the central portion to the lower surface of the central portion, and wherein the hollow support member comprises a hollow body and a plurality of hollow arms extending upwardly from the hollow body, the one or more upper open ends of the hollow support member comprising upper ends of the arms, wherein the passages are configured to receive gas from the upper ends of the arms.

5. The substrate support system of claim 4, wherein lower ends of the passages are located within support recesses in the lower surface of the central portion, each of the support recesses configured to closely receive an upper end of one of the arms.

6. The substrate support system of claim 1, wherein the one or more thinned portions comprise at least about 10% of an upper or lower surface of the central portion of the substrate holder.

7. The substrate support system of claim 1, wherein the porosity of the material forming the central portion is between about 20% to 30%.

8. The substrate support system of claim 1, wherein the substrate holder is formed of a porous composite silicon carbide.

9. The substrate support system of claim 1, wherein the substrate holder comprises a porous material having a density in a range of about 0.5 to 1.5 g/cm³.

10. The substrate support system of claim 1, wherein the at least one thinned portion has a thickness in a range of about of about 0.01-0.10 inch.

11. The substrate support system of claim 1, wherein the one or more thinned portions comprise cut-outs.

12. The substrate support system of claim 1, wherein the one or more recesses are formed in an upper surface of the central portion.

13. The substrate support system of claim 1, wherein the one or more recesses are formed in a lower surface of the central portion.

14. The substrate support system of claim 1, wherein the one or more recesses include recesses formed in an upper surface of the central portion and recesses formed in a lower surface of the central portion.

15. A substrate support system comprising a substrate holder for supporting a substrate, the substrate holder comprising a central portion having an upper surface, a lower surface, and a plurality of recesses, each recess being formed in one of the upper surface and the lower surface, each recess defining a thinned portion of the central portion, the central portion formed of a porous material.

16. The substrate support system of claim 15, further comprising a hollow support member having an inlet adapted to engage an outlet of a gas-conveyor to facilitate gas flow from the gas-conveyor into the hollow support member, the hollow support member having one or more upper open ends adapted to support the lower surface of the central portion of the substrate holder, the one or more upper open ends configured to convey gas upward through the central portion of the substrate holder.

17. The substrate support system of claim 16, wherein the one or more upper open ends of the hollow support member consists of one open end defined by an annular wall with an upper edge configured to stably support the substrate holder.

18. The substrate support system of claim 17, wherein the hollow support member comprises a generally horizontal base member and the annular wall, the annular wall extending upward from the base member.

19. The substrate support system of claim 15, wherein the porous material has a porosity in a range of about 10%-40%.

20. The substrate support system of claim 15, wherein the substrate holder includes at least one spacer extending upwardly from the central portion and having an upper support surface raised above the upper surface of the central portion, the spacer's upper support surface being configured to support the substrate such that a gap region is formed between the upper surface of the central portion and a bottom surface of the substrate.

21. The substrate support system of claim 20, wherein the gap region has a substantially uniform height.

22. The substrate support system of claim 15, wherein the plurality of recesses consists of about 80 to 5000 recesses.

23. The substrate support system of claim 15, wherein the upper or lower surface of the central portion of the substrate holder has a density of recesses of about 0.1 to 7 recesses per cm.

24. A method of processing a substrate, comprising:
providing a substrate holder comprising a central portion having one or more recesses defining thinned portions of the central portion, wherein the one or more thinned portions are configured to allow gas flow therethrough;
resting a substrate onto the substrate holder so that a gap region is formed between an upper surface of the central portion and a bottom surface of the substrate; and
directing an inert or cleaning gas through the one or more thinned portions of the substrate holder.

25. The method of claim 24, further comprising directing a generally horizontal flow of a reactive gas above the substrate, wherein the steps of directing the reactive gas and directing the inert or cleaning gas overlap in time.

26. The method of claim 24, wherein directing an inert or cleaning gas through the one or more thinned portions comprises:
providing one or more hollow arms;
positioning an upper end of each arm directly below one of a plurality of passages extending from the upper surface of the central portion to a lower surface of the central portion; and
directing the gas upwardly into each of the hollow arms, wherein the gas flows from the arms through the passages into the gap region and then flows down through the one or more thinned portions.

27. The method of claim 24, wherein directing an inert or cleaning gas through the one or more thinned portions comprises:
providing a hollow support member comprising a base member and an annular structure extending upwardly from the base member, the annular structure having an upper edge configured to restrict fluid flow across an interface between the upper edge and a lower surface of the substrate holder;
resting the lower surface of the central portion of the substrate holder on the upper edge of the annular structure of the hollow support member; and
directing the gas upwardly into the hollow support member, wherein the gas flows from the hollow support member upward through the one or more thinned portions of the central portion of the substrate holder.

28. The method of claim 24, further comprising directing a second flow of gas underneath and generally parallel to a lower surface of the central portion of the substrate holder.

29. The method of claim 24, wherein the one or more thinned portions comprise at least about 10% of the upper surface or a lower surface of the central portion of the substrate holder.

30. A substrate holder for supporting a substrate, the substrate holder comprising a central portion having an upper surface, a lower surface, and a plurality of recesses each formed in one of the upper surface and the lower surface, each recess defining a thinned portion of the central portion, the central portion formed of a porous material configured to permit gas flow therethrough without allowing light to pass therethrough, the central portion including at least one through-hole configured to receive an upward flow of gas.
